(19) United States
(12) Patent Application Publication
(10) Pub. No.: US 2019/0310494 A1
(43) Pub. Date: Oct. 10, 2019

(54) PROCESS FOR PREPARING CONTACT LENS WITH FILM BY PLASMA ENHANCED CHEMICAL VAPOR DEPOSITION

(71) Applicant: BRIGHTEN OPTIX CORP., Taipei City (TW)

(72) Inventors: Meng-Jiy WANG, Taipei City (TW); Wen-Pin LIN, Taipei City (TW)

(21) Appl. No.: 16/298,291

(22) Filed: Mar. 11, 2019

(30) Foreign Application Priority Data
Apr. 10, 2018 (TW) 107112304

(51) Int. Cl. G02C 7/04; G02B 1/04; C23C 16/30; H01J 37/32

(52) U.S. Cl. CPC G02C 7/04; G02B 1/043; H01J 2237/3321; H01J 37/32449; C23C 16/30

(57) ABSTRACT

The process for preparing contact lens with films by plasma enhanced chemical vapor deposition to apply plasma modification on contact lens to form hydrophilic functional groups on the surface of contact lens, and then respectively heating PEGMA and NVP into a gaseous state, and depositing the gaseous PEGMA and NVP on the substrate by means of PECVD so as to form the thin film on the substrate. By means of the thin film, the contact lens can reveal stable hydrophilicity and anti-fouling properties, so when the patient wear the contact lens, he or she does not feel uncomfortable foreign body sensation, significantly reducing the deposition of proteins and corneal infection risk.

This application claims the priority benefit of Taiwan patent application number 107112304, filed on Apr. 10, 2018.

### BACKGROUND OF THE INVENTION

### 1. Field of the Invention

The present invention relates to contact lens processing technology and more particularly, to a process for preparing contact lens with film prepared by plasma enhanced chemical vapor deposition, which creates a thin film on the surface of the contact lens through plasma modification and plasma enhanced chemical vapor deposition processes, enabling the contact lens to provide stable hydrophilicity and for reducing protein and bacteria adsorption.

### 2. Description of the Related Art

The developments of electronic products have facilitated the daily life of people. In particular, the heavily utilization of the 3C (computers, communications, and consumer) electronic products have become inevitable routine for most of the people. The overuses of 3C products among certain office workers, students, middle aged and elderly people may lead to vision impairment. The studies reported by King's College of London study at 2015 explored the possible links between the increased number of patients of myopia and the heavily uses of computers and smartphone.

However, in order to correct myopia, also known as near-sightness and short-sightness, people may need to wear glasses or contact lenses. At present, in order to correct myopia, most people wear glasses, contact lenses or orthokeratology lenses, or undergo a surgical procedure to permanently and safely correct their myopia. Contact lens manufacturers generally apply plasma surface modification on the contact lenses to improve the hydrophilicity of contact lenses. However, most of these hydrophilic effects can only last for about one or two weeks due to the following reasons:

(1) Reconstructing of chemical functional groups created during and after plasma treatment for the minimization of its surface energy and transfer to an equilibrium state.

(2) Initiation of new oxidation and degradation reactions on the surface and modification after exposure of the plasma-treated surface to air.

(3) Migration of low molecular weight oxidized macromolecules into the bulk film through the attainment of a more thermodynamically stable state with lower surface free energy.

(4) The tendency of the low molecular weight compounds to be released from the bulk material to the surface.

(5) Reorientation of the bulk polar chemical functional groups especially those that occur near the surface.

(6) Relaxation of the surface roughness, promoting hydrophobic recovery degree and inducing the formation of low molecular weight layer with lower free surface energy on the surface.

Because of the above reasons, the hydrophobicity of the contact lens increases gradually after a week of plasma surface modification treatment, and on the 10^{th} to the 14^{th} day, the water contact angle of the contact lens will return to the original water contact angle as the pristine contact lens. When the patient wears hydrophobic contact lenses, the patient will have an uncomfortable feeling because of the foreign body interaction, which forced the patient to give up wearing lenses. Further, the hydrophobic lenses were reported to be easily adhered by proteins which will cover on the lenses and therefore have impact on the user's vision and comfort. In addition, the protein rich environment is a breeding ground for bacteria. When the denatured protein initiates an allergic reaction, leading to giant papillary conjunctivitis (GPC), corneal infections such as acute red eyes, and prolonged wearing of contact lenses became impossible.

Therefore, it is desirable to provide contact lenses that can eliminate the aforementioned problems.

### SUMMARY OF THE INVENTION

The present invention has been accomplished under the circumstances in view. Therefore the first object of the present invention is to employ a process to prepare contact lens with a coating to introduce the hydrophilic functional groups on the surface of contact lens by plasma enhanced chemical vapor deposition of Poly (ethylene glycol)methacrylate (PEGMA) and N-vinyl-2-pyrrolidone (NVP), allowing the formation of a thin film on the surface of contact lens so that the contact lens can reveal stable hydrophilicity and antifouling properties provided by the thin film.

The second object of the present invention is to provide a process to prepare contact lens with a layer of thin film by plasma enhanced chemical vapor deposition, which introduces hydrophilic functional groups on the surface of contact lens with the deposited PEGMA and NVP functionalities, and this can slow down the process of hydrophobicity recovery for the surface to a state with the minimized surface energy and returning to a thermal equilibrium state, thereby a great extent the wetting properties of the surface for a long period of time.

The third object of the present invention is to provide a process to prepare contact lens with films by plasma enhanced chemical vapor deposition, which leads to the formation of hydrophilic functional groups on the surface of contact lens to improve the hydrophilicity. The functional group can also enhance adherence of Poly (ethylene glycol) methacrylate (PEGMA) and N-vinyl-2-pyrrolidone (NVP) to the contact lens surface to promote the stability of the thin films on the surface of contact lens.

The fourth object of the present invention is to provide a process to prepare contact lens with films by plasma enhanced chemical vapor deposition, which enables thin film to be formed on the surface of contact lens by PECVD so that the contact lens covered with this thin film will be ensured to be in contact with the cornea of patients, such that the hydrophilicity and fouling resistance of the contact lens can be carried out. The biocompatibility experiments confirmed that the deposition of PEGMA and NVP on the surface of contact lens does not induce significant cytotoxicity by PECVD, so that the patient can wear this contact lens with safety.

The fifth object of the present invention is to provide a process to prepare contact lens with films by plasma enhanced chemical vapor deposition, wherein the thin film is formed on the surface of contact lens by plasma enhanced chemical vapor deposition. Through the plasma enhanced chemical vapor deposition process, the thickness and uniformity of the thin film can be easily controlled to avoid that the thickness and uniformity of the thin film do not satisfy the requirements for product manufacturing process, thereby increasing the production yield.

The sixth object of the present invention is to provide a process to prepare contact lens with films by plasma enhanced chemical vapor deposition, wherein Poly (ethylene glycol) methacrylate (PEGMA) and N-vinyl-2-pyrrolidone (NVP) are heated into a gaseous state first, and then deposited to form the thin film on the surface of contact lens by plasma enhanced chemical vapor deposition. The implementation of plasma enhanced chemical vapor deposition, the amount of Poly (ethylene glycol) methacrylate (PEGMA) and N-vinyl-2-pyrrolidone (NVP) can be reduced, thereby reducing the environment impacts of subsequent waste liquid produced.

The other advantages and features of the present invention will be fully understood by reference to the following specification in conjunction with the accompanying drawings, in which the reference denote the components of structure.

### BRIEF DESCRIPTION OF THE DRAWINGS

FIG. 1 is the flow chart of the process for preparing contact lens with film by plasma enhanced chemical vapor deposition in accordance with the present invention (I).

FIG. 2 is the schematic diagram illustrating an application status of the plasma apparatus in accordance with the present invention.

FIG. 3 is the schematic sectional side view of the contact lens of the present invention before formation of the thin film.

FIG. 4 corresponds to FIG. 3, illustrating the thin film formed on the contact lens.

FIG. 5 is the water contact angle-vs-storage day data obtained from storing contact lens in bottle in accordance with the present invention.

FIG. 6 is the histogram illustrating the ability of the contact lens against the cell inhibition rate in accordance with the present invention

FIG. 7 is the histogram illustrating the ability of the contact lens against the growth of Escherichia coli.

FIG. 8 is the histogram illustrating the ability of the contact lens against the growth of Staphylococcus aureus.

FIG. 9 is the histogram illustrating the concentration of bovine serum albumin in the contact lens in accordance with the present invention.

FIG. 10 is the histogram illustrating the concentration of lysozyme in the contact lens in accordance with the present invention.

### DETAILED DESCRIPTION OF THE PREFERRED EMBODIMENT

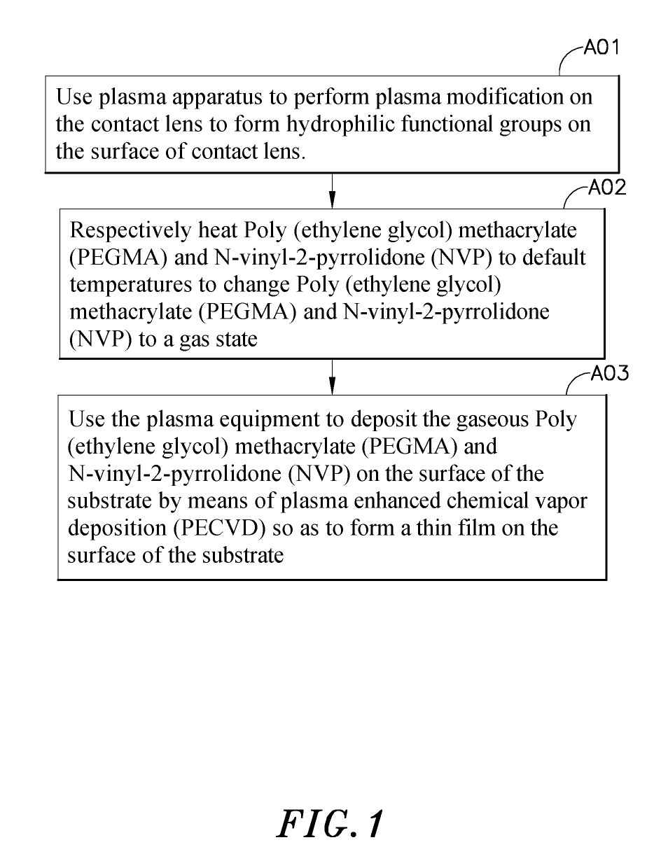

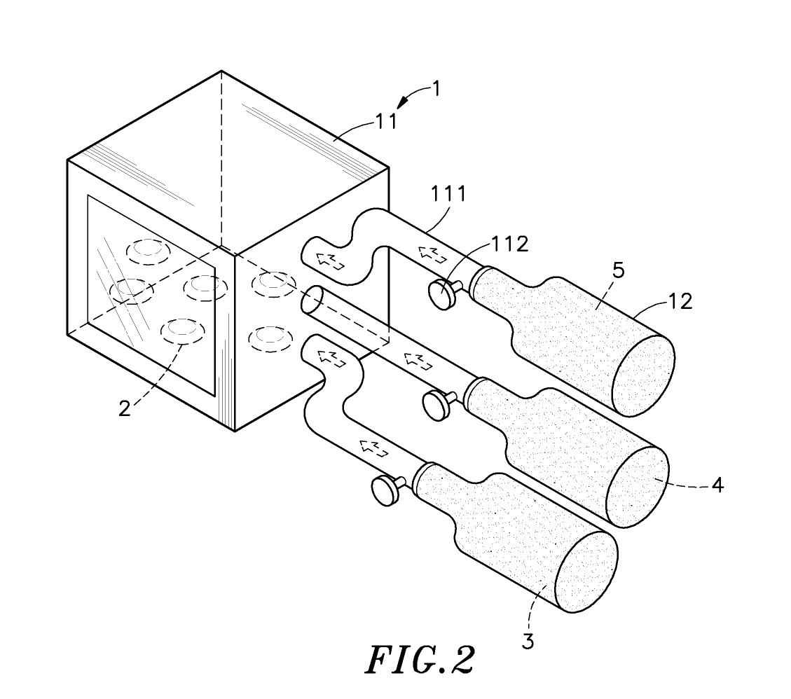

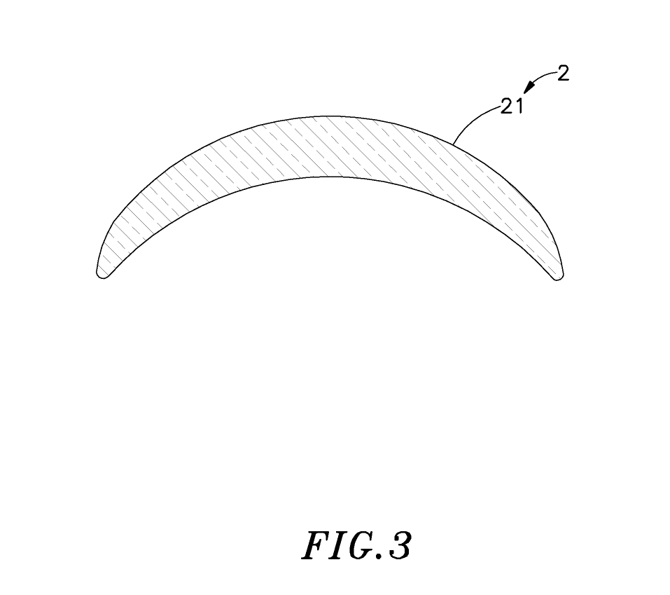

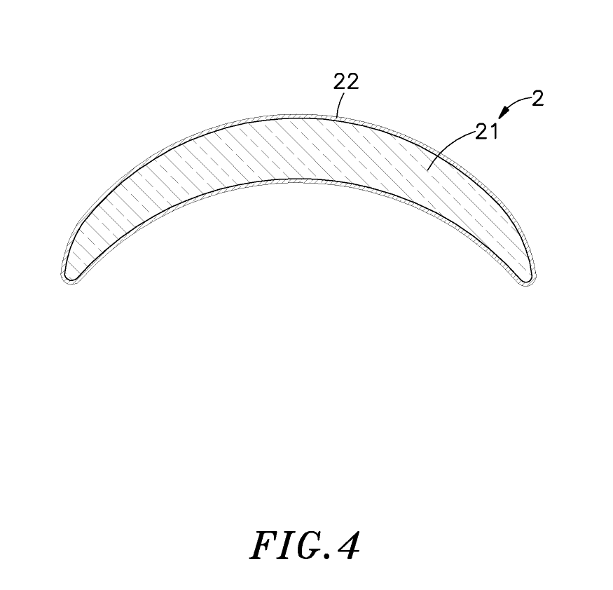

Referring to FIGS. 1-4, a process for preparing contact lens with films by plasma enhanced chemical vapor deposition comprises the steps of:

(A01) introducing hydrophilic functional groups on the contact lens 2 surface by using a plasma apparatus 1 to apply plasma modification on the surface of the contact lens 2 so as to form hydrophilic functional groups on the surface of the contact lens 2;

(A02) respectively heating Poly (ethylene glycol) methacrylate (PEGMA) 4 and N-vinyl-2-pyrrolidone (NVP) 5 to default temperatures to transform Poly (ethylene glycol) methacrylate (PEGMA) 4 and N-vinyl-2-pyrrolidone (NVP) 5 into a gaseous state; and

(A03) using the plasma apparatus 1 to deposit the gaseous Poly (ethylene glycol) methacrylate (PEGMA) 4 and N-vinyl-2-pyrrolidone (NVP) 5 on the plasma treated contact lens 2 by means of plasma enhanced chemical vapor deposition (PECVD) so as to form the thin film 22 on the surface of the plasma treated contact lens 2. The contact lens 2 is thus made.

The aforesaid contact lens 2 is preferably selected from contact lens materials such as polymethyl methacrylate (PMMA), fluorosilicone acrylate (FSA), polyhydroxyethyl methacrylate, GMMA, silicone hydrogel and lenses made from semi rigid gas permeable contact lenses.

In step (A01), the plasma apparatus 1 comprises a chamber 11 for the placement of the contact lens 2. The chamber 11 is connected to a gas cylinder 12 through a mass flow controller 111. The gas cylinder 12 accommodates Argon gas 3 for Argon plasma modification treatment. The plasma power (W) of the plasma apparatus 1, the period (s) of the plasma treatment, the flow rate (sccm) of the gas flows into the chamber 11 and the pressure (mTorr) in the chamber 11 are set to 70˜80 W, 90˜120 s, 5˜10 sccm and 80˜100 mTorr respectively, or preferably, 80 W, 120 s, 10 sccm and 100 mTorr respectively. Hydrophilic functional groups can be introduced stably on the contact lens 2 surface by the aforementioned parameters, and the water contact angle (WCA) on the contact lens 2 surface after plasma modification treatment can be 38±1.91°.

In step (A02), Poly (ethylene glycol) methacrylate (PEGMA) 4 is heated to 60˜80° C. and N-vinyl-2-pyrrolidone (NVP) 5 is heated to 40˜600C until vaporized.

In step (A03), the contact lens 2 after plasma modification is placed in the chamber 11 of the plasma apparatus 1; Poly (ethylene glycol) methacrylate (PEGMA) 4 and N-vinyl-2-pyrrolidone (NVP) 5 are stored in respective gas cylinders 12 that are respectively connected to the chamber 11 through respective mass flow controllers 111. Each mass flow controller 111 is provided with a throttle valve 112. When applying step (A03), set the pressure (mTorr) in the chamber 11 to the default value, then use the throttle valve 112 of the mass flow controller 111 to feed Poly (ethylene glycol) methacrylate (PEGMA) 4 through the respective mass flow controller 111 into the chamber 11, and then use the throttle valve 112 of the mass flow controller 111 to feed N-vinyl-2-pyrrolidone (NVP) 5 through the respective mass flow controller 111 into the chamber 11, and then operate the plasma apparatus according to the predetermined power output and deposition time to deposit Poly (ethylene glycol) methacrylate (PEGMA) 4 and N-vinyl-2-pyrrolidone (NVP) 5 on the surface of the contact lens 2, thereby forming the thin film 22 on the surface of the contact lens 2. In deposition process, gaseous Poly (ethylene glycol) methacrylate (PEGMA) 4 and N-vinyl-2-pyrrolidone (NVP) 5 are fed into the chamber 11 at rates of 5˜10 sccm. In operation, the pressure in the chamber 11 is adjusted to a vacuum state, then open the throttle valve 112 to feed gaseous Poly (ethylene glycol) methacrylate (PEGMA) 4 into the chamber 11 until the pressure in the chamber 11 is raised to 100˜120 mTorr. The system stands still for 5 to 10 minutes to let the chamber 11 be filled up with gaseous Poly (ethylene glycol) methacrylate (PEGMA) 4. Then, use the other throttle valve 112 to feed gaseous N-vinyl-2-pyrrolidone (NVP) 5 into the chamber 11 until the pressure in the chamber 11 is raised to 200˜240 mTorr. The system is then allowed to stand for 5 to 10 minutes to fully mixed gaseous Poly (ethylene glycol) methacrylate (PEGMA) 4 with gaseous N-vinyl-2-pyrrolidone (NVP) 5 in the chamber 11. Further, after activated the plasma apparatus, Poly (ethylene glycol) methacrylate (PEGMA) 4 and N-vinyl-2-pyrrolidone (NVP) 5 are deposited on the surface of the contact lens 2 under the plasma output power of 10˜20 W and deposition time 30˜60 minutes. Preferably, the deposition time is 60 minutes. Thus the contact lens 2 can reveal stable hydrophilicity and antifouling properties by the thin film 22.

In actual implementation of the present invention, place the contact lens 2 in the chamber 11 of the plasma apparatus 1, then feed Argon gas 3 from the respective gas cylinder 12 into the chamber 11 to be plasma-modified on the surface of the contact lens 2, thereby forming hydrophilic functional groups on the surface of the contact lens 2. Thereafter, heat Poly (ethylene glycol) methacrylate (PEGMA) 4 and N-vinyl-2-pyrrolidone (NVP) 5 in the respective gas cylinders 12 to 60˜80° C. and 40˜60° C. respectively, changing Poly (ethylene glycol) methacrylate (PEGMA) 4 and N-vinyl-2-pyrrolidone (NVP) 5 to a gaseous state, then change the pressure in the chamber 11 near a vacuum state, enabling Poly (ethylene glycol) methacrylate (PEGMA) 4 to be fed through the respective mass flow controller 111 into the chamber 11 to the status where the pressure in the chamber 11 is raised to 100˜120 mTorr. After Poly (ethylene glycol) methacrylate (PEGMA) 4 has been fed into the chamber 11, stand for 5˜10 minutes, and then open the throttle valve 112 to feed N-vinyl-2-pyrrolidone (NVP) 5 into the chamber 11 of the plasma apparatus 1 till that the pressure in the chamber 11 is raised to 200˜240 mTorr, and then stand for 5˜10 minutes to fully mixed the fed two gases. Thereafter, activate the plasma apparatus to deposit Poly (ethylene glycol) methacrylate (PEGMA) 4 and N-vinyl-2-pyrrolidone (NVP) 5 on the surface of the contact lens 2, thereby forming the thin film 22 on the surface of the contact lens 2. Thus, the desired contact lens 2 is obtained. Poly (ethylene glycol) methacrylate (PEGMA) 4 has the ability to reduce the adsorption of proteins and to increase fouling-resistant ability. The Biocompatibility tests (for example, in vitro cytotoxicity test, acute system toxicity test, ocular irritation test and skin sensitivity test, etc.) have proved that the contact lens 2 after PECVD will not induce significant cytotoxicity, so that the patient can wear this contact lens with safety. The thickness of the thin film 22 is so thin (100˜400 nm depending on the deposition time) that when the patient wear the contact lens 2, he or she would not undergo uncomfortable foreign body sensation. NVP and PEGMA are well-known for their biocompatible and hydrophilic properties, and can be deposited onto the surface of biomaterials to reduce the adhesion of proteins and suppression of cell/bacteria attachment. Furthermore, because NVP is a hydrophilic polymer and the depositing PEGMA has the ability to prevent nonspecific protein adsorption and to increase the fouling resistance, meaning the method has significantly reduced the deposition of proteins and to prevent the risk of corneal infection.

How does the above plasma apparatus 1 form Argon gas 3, Poly (ethylene glycol) methacrylate (PEGMA) 4 and N-vinyl-2-pyrrolidone (NVP) 5 into a plasma state through internal devices and components, and how to deposit Poly (ethylene glycol) methacrylate (PEGMA) 4 and N-vinyl-2-pyrrolidone (NVP) 5 on the surface of the contact lens 2 by plasma enhanced chemical vapor deposition are of the known art and not within the scope of the spirit of the present invention. Further, there are a lot of detailed components and they are not the focus of the invention of this case, so we will not go into details.

Further, when heating Poly (ethylene glycol) methacrylate (PEGMA) 4 and N-vinyl-2-pyrrolidone (NVP) 5, heating belts (not shown) are respectively wound around the surface of the gas cylinders 12 that contain Poly (ethylene glycol) methacrylate (PEGMA) 4 and N-vinyl-2-pyrrolidone (NVP) 5 respectively. By means of the heating belts, Poly (ethylene glycol) methacrylate (PEGMA) 4 and N-vinyl-2-pyrrolidone (NVP) 5 are heated to 60˜80° C. and 40˜60° C. respectively until vaporized. In actual application, other heating apparatus can be used to heat the respective gas cylinders 12. However, there are many equipment related to heating, so this embodiment is not intended to limit the scope of the present patent application, and other equivalent changes and modifications can be made thereunto without departing from the spirit and scope of the present invention.

Further, after Poly (ethylene glycol) methacrylate (PEGMA) 4 and N-vinyl-2-pyrrolidone (NVP) 5 are respectively changed into a gaseous state, Poly (ethylene glycol) methacrylate (PEGMA) 4 is fed into the chamber 11 of the plasma apparatus 1 first, and then N-vinyl-2-pyrrolidone (NVP) 5 is fed into the chamber 11. Due to the lower molecular weight of N-vinyl-2-pyrrolidone (NVP) 5, N-vinyl-2-pyrrolidone (NVP) 5 will first deposit and polymerize with the contact lens 2, and Poly (ethylene glycol) methacrylate (PEGMA) 4 will then deposit and polymerize with the contact lens 2, thereby increasing the atom content of nitrogen (N) and oxygen (O) on the surface of the contact lens 2 and decreasing the atom content of carbon (C), fluorine (F) and silicon (SI). The increase of the atom content of nitrogen (N) and oxygen (O) on the surface of the contact lens 2 will increase the hydrophilicity of the contact lens 2.

However, after Poly (ethylene glycol) methacrylate (PEGMA) 4 and N-vinyl-2-pyrrolidone (NVP) 5 are deposited on the surface of the contact lens 2, the functional groups on the surface of the contact lens 2 will undergo grafting polymerization 5 with Poly (ethylene glycol) methacrylate (PEGMA) 4 and N-vinyl-2-pyrrolidone (NVP) 5 and cross-linking will occur between Poly (ethylene glycol) methacrylate (PEGMA) 4 and N-vinyl-2-pyrrolidone (NVP) 5. Through polymerization and cross-linking, the contact lens 2 can reveal stable hydrophilicity.

After deposition of Poly (ethylene glycol) methacrylate (PEGMA) 4, the hydrophilicity of the lens can be increased, therefore, more N-vinyl-2-pyrrolidone (NVP) 5 can be grafted, enhancing hydrophilicity.

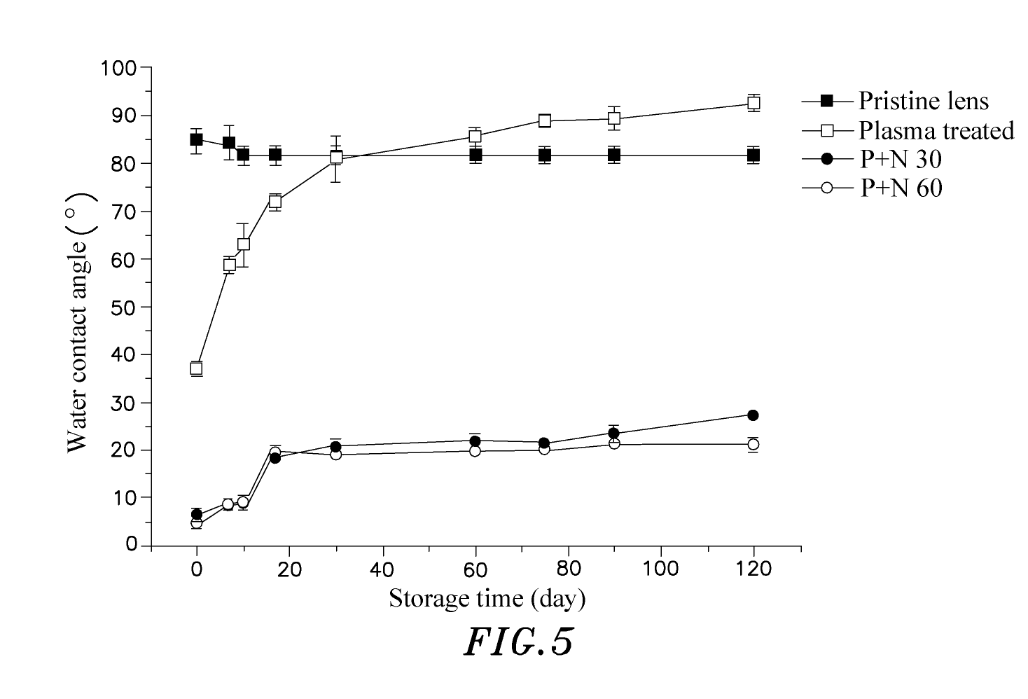

FIG. 5 is the water contact angle-vs-storage day data obtained from storage of contact lenses in contact lens bottles. In FIG. 5, the vertical axis is the water contact angle; the horizontal axis is the duration of storage (in days); the solid square curve (Pristine) is the control curve of the pristine contact lens; the hollow square curve (plasma treated) is an experimental curve of the contact lens only treated with plasma; the solid round curve (P+N 30) is the experimental curve of the contact lens of the present invention after plasma deposition for 30 minutes; the hollow round curve (P+N 60) is the experimental curve of the contact lens of the present invention after plasma deposition for 60 minutes.

It can be clearly seen from the foregoing multiple curves that when stored for 120 days, the water contact angle of the thin film 22 coated contact lenses 2 of the present invention is significantly lower than the pristine contact lens and the contact lens which only undergo plasma treatment. This shows the contact lens 2 with the thin film 22 can reveal stable hydrophilicity.

When stored for 120 days, the water contact angle of the hollow round curve (P+N 60) is the lowest (about 22°) in the multiple curves. So, people can know that when PECVD is used for 60 minutes, the contact lens 2 can reveal most stable hydrophilicity.

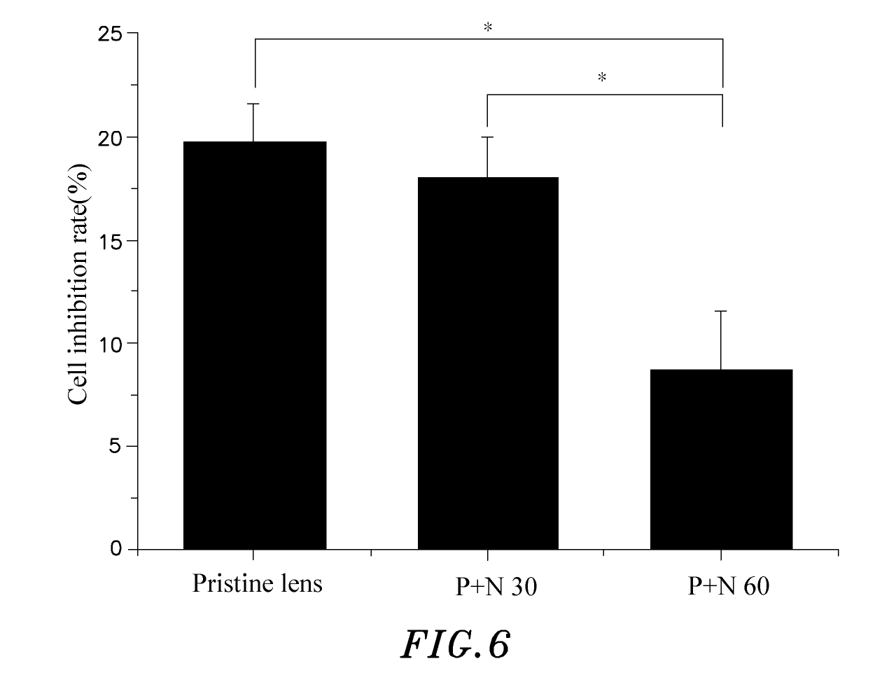

Referring to FIG. 6 again, the histogram of the contact lens cell inhibition rate of the present invention is shown. In the histogram of the contact lens cell inhibition rate, the vertical axis is the inhibition ratio (%), and the horizontal axis is the types of contact lenses 2. The histogram representing cell viability measured by MTT assay. It can be clearly seen from the diagram that the inhibition rate of the contact lens 2 is the lowest (about 8%) when plasma is used for 60 minutes, so that it can be known that the inhibition of cell survival will be the lowest and the biocompatibility will be the highest after deposition of Poly (ethylene glycol) methacrylate (PEGMA) 4 and N-vinyl-2-pyrrolidone (NVP) 5 on the contact lens 2 for 60 minutes.

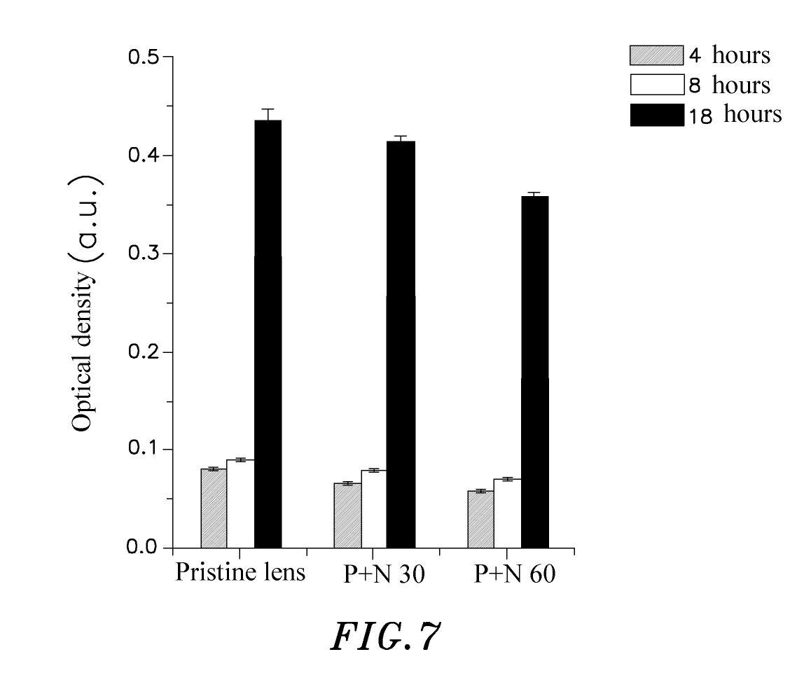

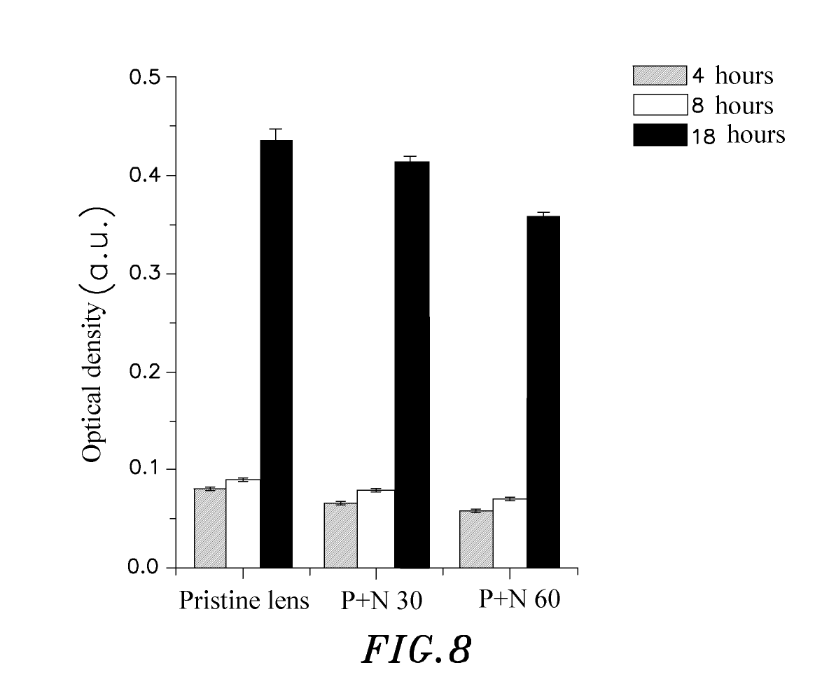

Referring to FIGS. 7 and 8, which are the histograms of the contact lens against the growth of Escherichia coli and Staphylococcus aureus respectively. It can be clearly seen from the diagrams that the vertical axis in the diagrams is the optical density, and the horizontal axis is the types of contact lenses 2. The less the optical density of Escherichia coli or Staphylococcus aureus that can be detected on the different types of contact lenses 2 for 4, 8, and 18 hours, the less number of bacteria on the contact lenses 2 is. The diagrams show that the optical density that can be detected for 4, 8, and 18 hours after the contact lens 2 is deposited by PECVD for 60 minutes is the lowest among a plurality of contact lenses, and thus the contact lens 2 of the present invention shows the best outcome for the fouling resistance.

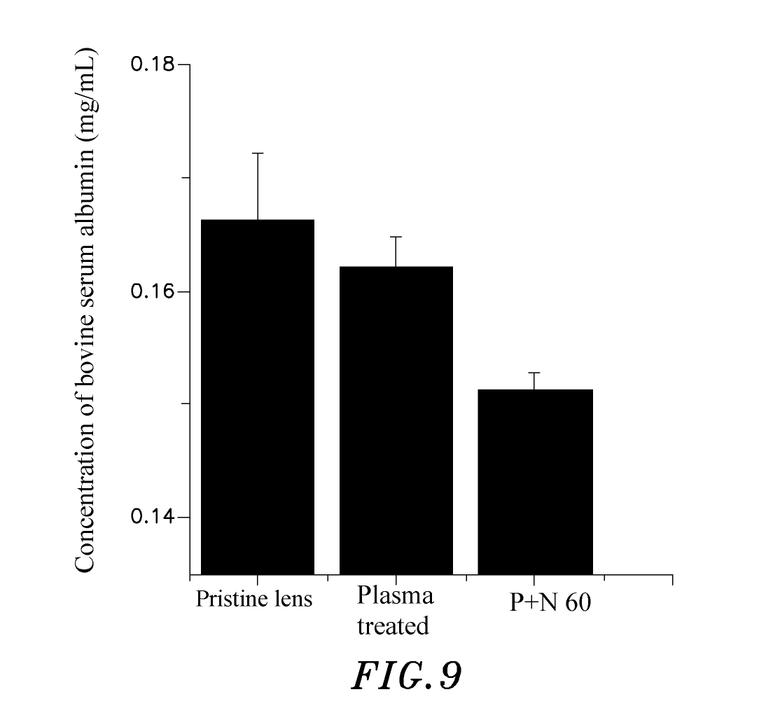

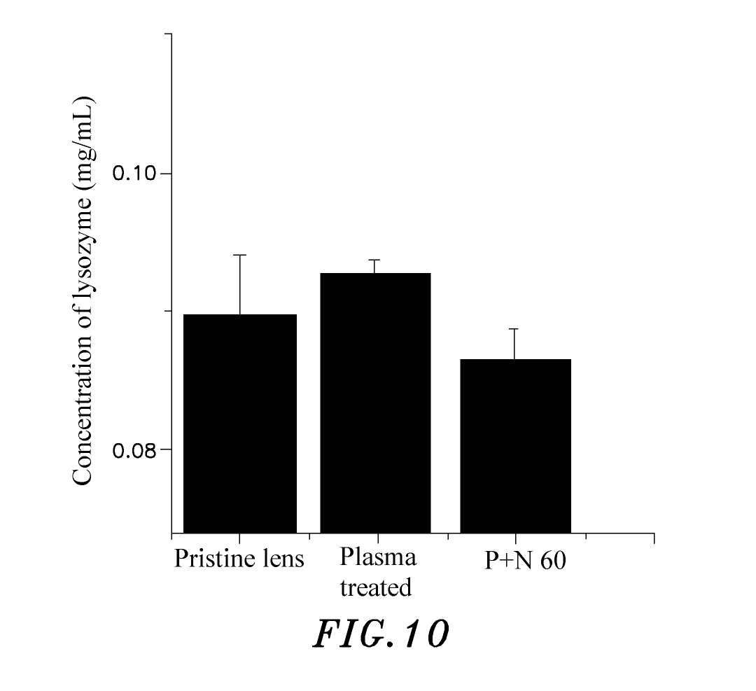

See also FIGS. 9 and 10, which are the histograms of the concentration of bovine serum albumin in the contact lens of the present invention and the histogram of lysozyme concentration in the contact lens of the present invention. In FIG. 9, the vertical axis is the concentration (mg/mL) of bovine serum albumin (BSA); the horizontal axis is the types of contact lenses 2. In FIG. 10, the vertical axis is the concentration (mg/mL) of lysozyme; the horizontal axis is the types of contact lenses 2. In FIGS. 9 and 10, the contact lens without any treatment is referenced by “Pristine”; the contact lens processed through plasma treatment is referenced by “Plasma treated”; the contact lens 2 of the present invention that is processed by PECVD for 60 minutes is referenced by “P+N 60”. The lower the concentration of bovine serum albumin or lysozyme that can be detected on the surface of the contact lens 2, the less protein on the contact lens 2 is.

The diagrams show that the contact lens 2 was deposited by PECVD for 60 minutes, the protein concentration that can be detected was the lowest, and thus shows the best outcome for the fouling resistance. Because long-term precipitate is related to lens deterioration, the present invention possible extend the life expectancy of the contact lens 2.

In conclusion, the invention has the advantages as follow:

1. The contact lens 2 is treated through plasma modification treatment, and then gaseous Poly (ethylene glycol) methacrylate (PEGMA) 4 and N-vinyl-2-pyrrolidone (NVP) 5 are deposited on the contact lens 2 by plasma enhanced chemical vapor deposition so that the thin film 22 is formed on the surface of the contact lens 2, and thus, the contact lens 2 can reveal stable hydrophilicity and anti-fouling properties. Due to cross-linking between Poly (ethylene glycol) methacrylate (PEGMA) 4 and N-vinyl-2-pyrrolidone (NVP) 5, maintain the stable hydrophilic surface of the contact lens 2. In addition, the present invention has been verified to reduce the deposition of proteins on the surface of the contact lens 2, thereby increasing the comfort and life expectancy of the contact lens 2 when worn.

2. After plasma modification, hydrophilic functional groups are introducedga on the contact lens 2 surface, and the functional groups are grated with Poly (ethylene glycol) methacrylate (PEGMA) 4 and N-vinyl-2-pyrrolidone (NVP) 5, so that the functional groups can slow down the process of hydrophobicity recovery for recovering to a state with minimized surface energy and returning to a thermal equilibrium state, thereby achieving the long-lasting hydrophilic surface.

3. After the plasma-modification, hydrophilic functional groups are formed on the contact lens 2 surface to improve the hydrophilicity, and the functional groups can also enhance adherence of Poly (ethylene glycol) methacrylate (PEGMA) 4 and N-vinyl-2-pyrrolidone (NVP) 5 to the contact lens 2 surface to achieve the effect of increasing the formation and stability of the thin film 22 on the contact lens 2 surface.

4. Poly (ethylene glycol) methacrylate (PEGMA) 4 and N-vinyl-2-pyrrolidone (NVP) 5 are heated into a gaseous state first, and then deposited to form the thin film 22 on the contact lens 2 surface by plasma enhanced chemical vapor deposition. Subject to the implementation of plasma enhanced chemical vapor deposition, the amount of Poly (ethylene glycol) methacrylate (PEGMA) 4 and N-vinyl-2-pyrrolidone (NVP) 5 can be reduced, thereby reducing the environment impacts of subsequent waste liquid produced.

5. The thin film 22 is formed on the surface of the contact lens 2 by plasma enhanced chemical vapor deposition. Through the plasma enhanced chemical vapor deposition, the thickness and uniformity of the thin film 22 can be easily controlled to avoid that the thickness and uniformity of the thin film 22 do not satisfy the requirements for product manufacturing process, thereby increasing the production yield rate.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A process for preparing contact lens with films by plasma enhanced chemical vapor deposition, comprising the steps of:
(A01) using a plasma apparatus to apply plasma modification on a surface of a contact lens to form hydrophilic functional groups on the surface of said substrate;
(A02) respectively heating Poly (ethylene glycol) methacrylate (PEGMA) and N-vinyl-2-pyrrolidone (NVP) to default temperatures and turn said Poly (ethylene glycol) methacrylate (PEGMA) and said N-vinyl-2-pyrrolidone (NVP) into a gaseous state; and
(A03) using said plasma apparatus to deposit the gaseous Poly (ethylene glycol) methacrylate (PEGMA) and N-vinyl-2-pyrrolidone (NVP) on the surface of said substrate by means of plasma enhanced chemical vapor deposition (PECVD) so as to form thin films on the surface of said substrate.

2. The process for preparing contact lens with films by plasma enhanced chemical vapor deposition as claimed in claim 1, wherein said substrate of said contact lens is preferably selected from contact lens materials such as polymethyl methacrylate (PMMA), fluorosilicone acrylate (FSA), polyhydroxyethyl methacrylate, GMMA and lenses made from semi rigid gas permeable contact lenses.

3. The process for preparing contact lens with films by plasma enhanced chemical vapor deposition as claimed in claim 1, wherein said plasma apparatus used in step (A01) comprises a chamber for placement of said substrate, a gas cylinder containing Argon gas, and a mass flow controller connected between said chamber and said gas cylinder and adapted for introducing Argon gas from said gas cylinder into said chamber.

4. The process for preparing contact lens with films by plasma enhanced chemical vapor deposition as claimed in claim 1, wherein said plasma apparatus used in step (A01) comprises a chamber for placement of said substrate; in the plasma modification process, the plasma power of said plasma apparatus, the period of the said lens exposure to plasma, the flow rate of the gas flows into said chamber and the pressure in said chamber are set to 70˜80 W, 90˜120 s, 5˜10 sccm and 80˜100 mTorr respectively

5. The process for preparing contact lens with films by plasma enhanced chemical vapor deposition as claimed in claim 4, wherein in the plasma modification process, the plasma power of said plasma apparatus, the period of the said lens exposure to plasma, the flow rate of the gas flows into said chamber and the pressure in said chamber are preferably, 80 W, 120 s, 10 sccm and 100 mTorr respectively.

6. The process for preparing contact lens with films by plasma enhanced chemical vapor deposition as claimed in claim 1, wherein in step (A02), the default temperatures are 60˜80° C. for said Poly (ethylene glycol) methacrylate (PEGMA) and 40˜60° C. for said N-vinyl-2-pyrrolidone (NVP).

7. The process for preparing contact lens with films by plasma enhanced chemical vapor deposition as claimed in claim 1, wherein said plasma apparatus used in step (A03) comprises a chamber for placement of said substrate, a plurality of gas cylinders respectively containing said gaseous Poly (ethylene glycol) methacrylate (PEGMA) and said gaseous N-vinyl-2-pyrrolidone (NVP), a plurality of mass flow controllers respectively connected between said gas cylinders and said chamber for introducing said gaseous Poly (ethylene glycol) methacrylate (PEGMA) and said gaseous N-vinyl-2-pyrrolidone (NVP) from said gas cylinder into said chamber, and a throttle valve arranged on each said mass flow controller for gas flow rate control.

8. The process for preparing contact lens with films by plasma enhanced chemical vapor deposition as claimed in claim 7, wherein adjusting the pressure (mTorr) in said chamber to the default value, then opening the respective said throttle valve of the respective said mass flow controller to feed said gaseous Poly (ethylene glycol)methacrylate (PEGMA) through the respective said mass flow controller into said chamber, and then opening the respective said throttle valve of the respective said mass flow controller to feed said gaseous N-vinyl-2-pyrrolidone (NVP) through the respective said mass flow controller into said chamber, and then operating said plasma apparatus according to the predetermined power output and deposition time to deposit said Poly (ethylene glycol) methacrylate (PEGMA) and said N-vinyl-2-pyrrolidone (NVP) on the surface of said substrate, thereby polymerizing thin films on a surface of said substrate.

9. The process for preparing contact lens with films by plasma enhanced chemical vapor deposition as claimed in claim 8, wherein said gaseous Poly (ethylene glycol) methacrylate (PEGMA) and said gaseous N-vinyl-2-pyrrolidone (NVP) are fed into said chamber at rates of 5˜10 sccm; in operation, changing the pressure in said chamber to near vacuum state, then opening the respective said throttle valve to feed said gaseous Poly (ethylene glycol) methacrylate (PEGMA) into said chamber until the pressure in said chamber is raised to 100˜120 mTorr, and then standing still for 5 to 10 minutes to fill up with said gaseous Poly (ethylene glycol) methacrylate (PEGMA) in said chamber, and then, opening the respective said throttle valve to feed said gaseous N-vinyl-2-pyrrolidone (NVP) into said chamber until the pressure in said chamber is raised to 200˜240 mTorr, and then standing still for 5 to 10 minutes to fully mixed said gaseous Poly (ethylene glycol) methacrylate (PEGMA) with said gaseous N-vinyl-2-pyrrolidone (NVP) in said chamber prior to activate said plasma apparatus.

10. The process for preparing contact lens with films by plasma enhanced chemical vapor deposition as claimed in claim 8, wherein after activated said plasma apparatus, said Poly (ethylene glycol) methacrylate (PEGMA) and said N-vinyl-2-pyrrolidone (NVP) are deposited on the surface of said substrate under the plasma output power of 10˜20 W and deposition time 30˜60 minutes, or preferably the deposition time of 60 minutes.
